(19) United States
(12) Patent Application Publication
(10) Pub. No.: US 2024/0162052 A1
(43) Pub. Date: May 16, 2024

(54) SUBSTRATE PROCESSING APPARATUS, SUBSTRATE PROCESSING METHOD, AND SUBSTRATE

(71) Applicant: Tokyo Electron Limited, Tokyo (JP)

(72) Inventors: Takanori OBARU, Koshi City (JP); Nobuhiko MOURI, Koshi City (JP)

(21) Appl. No.: 18/501,309

(22) Filed: Nov. 3, 2023

(30) Foreign Application Priority Data
Nov. 10, 2022 (JP) 2022-180196

(51) Int. Cl. H01L 21/67; H01L 21/687

(52) U.S. Cl. CPC H01L 21/67023; H01L 21/68764

(57) ABSTRACT

A substrate processing apparatus that processes a substrate with a processing liquid, includes: a processing container; a first substrate holder configured to horizontally hold the substrate inside the processing container; a rotation drive configured to rotate the first substrate holder about a vertical rotation central axis; a second substrate holder configured to horizontally hold the substrate inside the processing container; a movement drive configured to move the first substrate holder and the second substrate holder relative to each other; and a controller configured to control the rotation drive and the movement drive, wherein the controller performs control to repeat contact between the first substrate holder and the substrate by changing a contact position of the substrate with the first substrate holder.

### CROSS-REFERENCE TO RELATED APPLICATION

This application is based upon and claims the benefit of priority from Japanese Patent Application No. 2022-180196, filed on Nov. 10, 2022, the entire contents of which are incorporated herein by reference.

### TECHNICAL FIELD

The present disclosure relates to a substrate processing apparatus, a substrate processing method, and a substrate.

### BACKGROUND

A substrate processing apparatus disclosed in Patent Document 1 includes two attraction pads, a liquid receiving cup, a spin chuck, a housing, a first cleaner, and a second cleaner. The two attraction pads are used to attractively hold a lower surface of a substrate horizontally. The liquid receiving cup is connected to the two attraction pads. The spin chuck is used to attractively hold horizontally the lower surface of the substrate received from the attraction pads. The housing has a top opening. A drain pipe for discharging a cleaning liquid and an exhaust pipe for discharging an airflow are provided at a bottom of the housing. The first cleaner serves to clean an upper surface of the substrate. The second cleaner serves to clean the lower surface of the substrate.

### PRIOR ART DOCUMENTS

### Patent Documents

Patent Document 1: Japanese Laid-open Publication No. 2020-043156

### SUMMARY

According to one embodiment of the present disclosure, a substrate processing apparatus that processes a substrate with a processing liquid, includes: a processing container; a first substrate holder configured to horizontally hold the substrate inside the processing container; a rotation drive configured to rotate the first substrate holder about a vertical rotation central axis; a second substrate holder configured to horizontally hold the substrate inside the processing container; a movement drive configured to move the first substrate holder and the second substrate holder relative to each other; and a controller configured to control the rotation drive and the movement drive, wherein the controller performs a first control to repeat contact between the first substrate holder and the substrate by changing a first contact position of the substrate with the first substrate holder.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view illustrating a substrate processing apparatus according to an embodiment, and illustrates an example of step S104 in FIG. 7.

FIG. 2 is a cross-sectional view illustrating an example of step S104 in FIG. 7.

FIG. 3 is a plan view illustrating an example of step S102 in FIG. 7.

FIG. 4 is a cross-sectional view illustrating an example of step S102 in FIG. 7.

FIG. 5 is a cross-sectional view illustrating an exemplary operation of lifting pins.

FIG. 6 is a cross-sectional view illustrating an exemplary operation of the lifting pins following FIG. 5.

FIG. 7 is a flowchart illustrating a substrate processing method according to an embodiment.

FIG. 8 is a bottom view illustrating an exemplary cleaning of a first substrate holder.

FIG. 9 is a side view illustrating an example of a substrate.

FIG. 10 is a bottom view illustrating an example of a first straight line.

FIG. 11 is a bottom view illustrating an example of a second straight line.

FIG. 12 is a flowchart illustrating an exemplary cleaning of the first substrate holder.

FIG. 13 is a bottom view illustrating an exemplary cleaning of the lifting pins.

FIG. 14 is a bottom view illustrating an exemplary cleaning of a second substrate holder.

FIG. 15 is a cross-sectional view illustrating a first modification of the first substrate holder and the second substrate holder and is a cross section illustrating a state where the second substrate holder holds the substrate.

FIG. 16 is a cross-sectional view illustrating the first modification of the first substrate holder and the second substrate holder and is a cross section illustrating a state where the lifting pins hold the substrate.

FIG. 17 is a cross-sectional view illustrating the first modification of the first substrate holder and the second substrate holder and is a cross section illustrating a state where the first substrate holder holds the substrate.

FIG. 18 is a cross-sectional view illustrating a second modification of the first substrate holder and the second substrate holder and is a cross section illustrating a state where the second substrate holder holds the substrate.

FIG. 19 is a cross-sectional view illustrating the second modification of the first substrate holder and the second substrate holder and is a cross section illustrating a state where the lifting pins hold the substrate.

FIG. 20 is a cross-sectional view illustrating the second modification of the first substrate holder and the second substrate holder and is a cross section illustrating a state where the first substrate holder holds the substrate.

### DETAILED DESCRIPTION

Hereinafter, embodiments of the present disclosure will be described with reference to the accompanying drawings. In addition, in each drawing, the same reference numerals will be given to the same or corresponding components, and descriptions thereof may be omitted. In this specification, an X-axis direction, a Y-axis direction, and a Z-axis direction are directions perpendicular to one another. The X-axis direction and the Y-axis direction are a horizontal direction, and the Z-axis direction is a vertical direction.

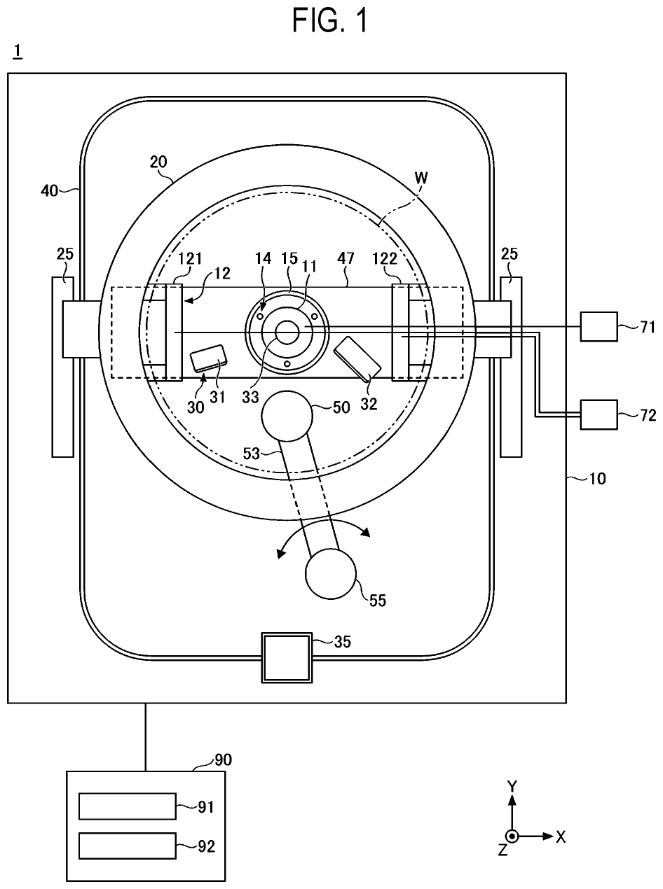

An example of a substrate processing apparatus 1 will be described with reference to FIGS. 1 to 6. The substrate processing apparatus 1 processes a substrate W with a processing liquid. The substrate W is, for example, a semiconductor substrate or a glass substrate. The semiconductor substrate is a silicon wafer, a compound semiconductor wafer, or the like. A device may be formed in advance on at least one of a lower surface and an upper surface of the substrate W. The device includes a semiconductor element, a circuit, a terminal, or the like.

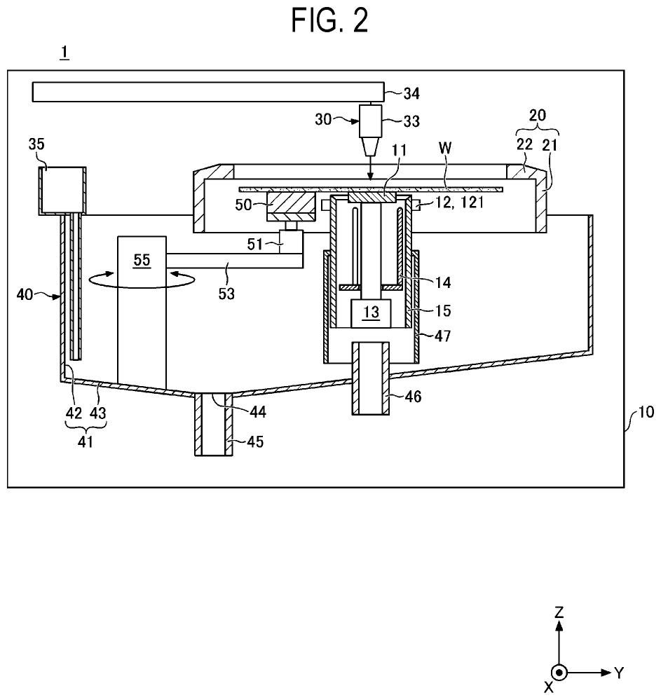

As mainly illustrated in FIG. 2, the substrate processing apparatus 1 includes, for example, a processing container 10, a first substrate holder 11, a second substrate holder 12, a rotation drive 13, a cup 20, a movement drive 25 (see FIG. 1), a processing liquid supplier 30, a processing tank 40, a drain pipe 45, an exhaust pipe 46, an exhaust pipe cover 47, a friction body 50, a friction body mover 55, and a controller 90 (see FIG. 1).

The first substrate holder 11 horizontally holds the substrate W inside the processing container 10. The first substrate holder 11 comes into contact with only a portion of the lower surface of the substrate W. The first substrate holder 11 attracts, for example, a central portion of the lower surface of the substrate W. The first substrate holder 11 is, for example, a spin chuck that is rotatably driven by the rotation drive 13. The first substrate holder 11 is rotated about a vertical rotation central axis. The first substrate holder 11 may be movable in the Z-axis direction.

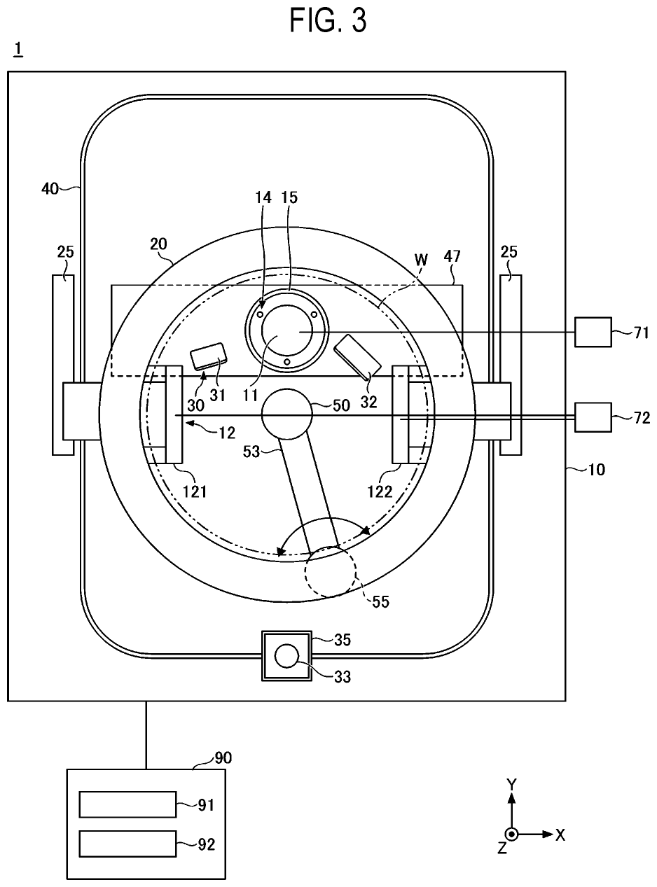

The first substrate holder 11 is connected to a first attractive-force applier 71 (see FIGS. 1 and 3). The first attractive-force applier 71 applies, to the first substrate holder 11, an attractive force for attracting the substrate W. The first attractive-force applier 71 may manifest the attractive force (vacuum attractive force) by gas suction but may also manifest the attractive force (electrostatic attractive force) by voltage application. The first attractive-force applier 71 performs the manifestation and dissipation of the attractive force under the control of the controller 90.

A plurality of lifting pins 14 are arranged around the first substrate holder 11. The plurality of lifting pins 14 lower or raise the substrate W relative to the first substrate holder 11 or the second substrate holder 12. The plurality of lifting pins 14 are arranged at equal intervals in a circumferential direction of the first substrate holder 11. The plurality of lifting pins 14 move up and down around the first substrate holder 11, thus transferring the substrate W between the first substrate holder 11 or the second substrate holder 12 and a transfer arm (not illustrated).

Further, a gas discharge ring 15 is arranged around the first substrate holder 11. The gas discharge ring 15 surrounds the first substrate holder 11 to form a ring-shaped gas curtain toward the lower surface of the substrate W. The gas curtain restricts the processing liquid from flowing inward from the outside to protect the first substrate holder 11. The gas curtain also protects the plurality of lifting pins 14 arranged inward of the gas curtain.

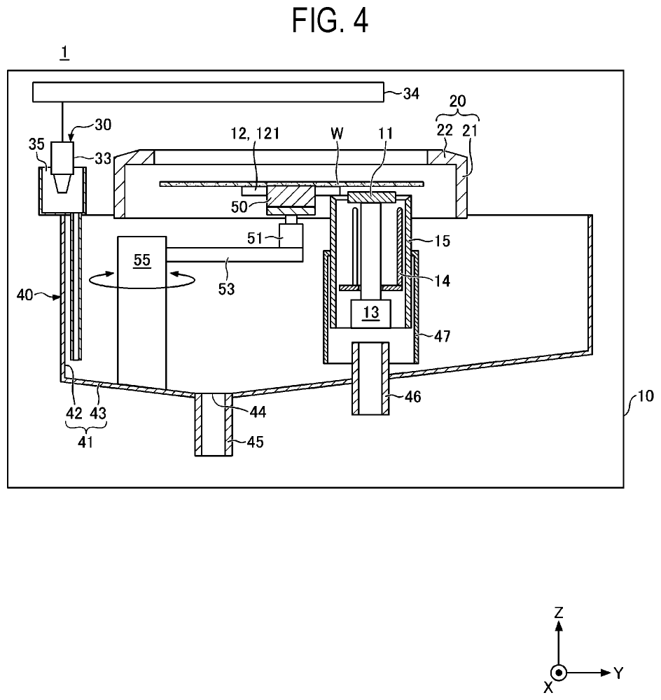

The second substrate holder 12 horizontally holds the substrate 10 inside the processing container 10. The second substrate holder 12 comes into contact with only a portion of the lower surface of the substrate W. As illustrated in FIGS. 3 and 4, the second substrate holder 12 attracts, for example, an outer peripheral portion of the lower surface of the substrate W. The second substrate holder 12 includes a pair of attraction pads 121 and 122 arranged at an interval in the X-axis direction. The pair of attraction pads 121 and 122 are arranged with the first substrate holder 11 therebetween in the X-axis direction. The second substrate holder 12 is connected to the cup 20 and is movable together with the cup 20 in the horizontal direction (Y-axis direction) and in the vertical direction.

The second substrate holder 12 is connected to a second attractive-force applier 72 (see FIGS. 1 and 3). The second attractive-force applier 72 applies, to the second substrate holder 12, an attractive force for attracting the substrate W. The second attractive-force applier 72 may manifest the attractive force (vacuum attractive force) by gas attraction but may also manifest the attractive force (electrostatic attractive force) by voltage application. The second attractive-force applier 72 performs the manifestation and dissipation of the attractive force under the control of the controller 90.

The cup 20 has a ring shape that is open in both upward and downward directions, and encloses the outer periphery of the substrate W held by the first substrate holder 11 or the second substrate holder 12. The cup 20 has a cylindrical vertical wall 21 and a top wall 22 that protrudes radially inward from an upper end of the cylindrical vertical wall 21. The cup 20 receives the processing liquid supplied to the substrate W.

The movement drive 25 moves the second substrate holder 12 in the horizontal direction (Y-axis direction) perpendicular to the rotation central axis of the first substrate holder 11 and in the vertical direction (Z-axis direction). The movement drive 25 moves the second substrate holder 12 together with the cup 20. The cup 20 may be moved inside the processing tank 40. When viewed from above, a side surface 42 of the processing tank 40 encloses the entire movement range of the cup 20.

The processing liquid supplier 30 supplies the processing liquid to the substrate W enclosed by the cup 20. The processing liquid includes, for example, a chemical liquid and a rinse liquid. The chemical liquid is not particularly limited, but is, for example, SC1 (a mixed liquid of ammonia, hydrogen peroxide, and water). The chemical liquid may also be an etching liquid or a peel-off liquid, in addition to a cleaning liquid that removes contaminants adhering to the substrate W. The rinse liquid is, for example, DIW (deionized water). The chemical liquid and the rinse liquid may be supplied to the substrate W in this order.

The processing liquid supplier 30 includes lower nozzles 31 and 32 (see FIGS. 1 and 3) that supply the processing liquid to the lower surface of the substrate W. Each of the lower nozzles 31 and 32 is connected to a source of the processing liquid via a pipe (not illustrated). A valve and a flow controller are provided in the pipe. When the valve opens a flow path of the pipe, the processing liquid is discharged from the lower nozzles 31 and 32. A discharge amount of the processing liquid is controlled by the flow controller. On the other hand, when the valve closes the flow path of the pipe, the discharge of the processing liquid is stopped.

The processing liquid supplier 30 includes an upper nozzle 33 (see FIG. 2) that supplies the processing liquid to the upper surface of the substrate W. Like the lower nozzles 31 and 32, the upper nozzle 33 is connected to the source of the processing liquid via a pipe (not illustrated). The upper nozzle 33 may be a two-fluid nozzle, and may atomize the processing liquid using a gas such as a N₂ gas to aerosolize and spray it.

The processing liquid supplier 30 includes a nozzle mover 34 that moves the upper nozzle 33 in the horizontal and vertical directions. The nozzle mover 34 moves the upper nozzle 33 between a position at which the processing liquid is supplied to the substrate W enclosed by the cup 20 (see FIG. 2) and a position at which a discharge hole of the upper nozzle 33 is accommodated in a nozzle bus 35 (see FIG. 4).

The nozzle bus 35 is also called a dummy dispensing port. By discharging an old processing liquid (e.g., processing liquid with a reduced temperature) accumulated in the upper nozzle 33 into the nozzle bus 35 immediately before supplying the processing liquid from the upper nozzle 33 to the substrate W, it is possible to supply a new processing liquid (e.g., processing liquid with a desired controlled temperature) to the substrate W. A discharge pipe is provided on a bottom wall of the nozzle bus 35. The discharge pipe discharges the processing liquid accumulated in the nozzle bus 35 to the interior of the processing tank 40. The discharge pipe is provided vertically. The processing liquid flows downward through the discharge pipe by gravity. A lower end of the discharge pipe is positioned higher than a bottom surface 43 of the processing tank 40.

The processing tank 40 collects the processing liquid falling from the cup 20. The processing tank 40 has, for example, a box shape with an open top. An inner wall surface 41 of the processing tank 40 has the side surface 42 and the bottom surface 43. The bottom surface 43 has an outlet 44 through which the processing liquid is discharged. The drain pipe 45 is provided at the outlet 44. The drain pipe 45 discharges the processing liquid from the interior of the processing tank 40 to the outside. In addition to the drain pipe 45, the exhaust pipe 46 is provided on the bottom surface 43 of the processing tank 40.

The exhaust pipe 46 discharges a gas from the interior of the processing tank 40 to the outside. The exhaust pipe 46 protrudes upward from the bottom surface 43 of the processing tank 40. The top of the exhaust pipe 46 is covered with the exhaust pipe cover 47. The exhaust pipe cover 47 prevents droplets of the processing liquid from entering the exhaust pipe 46. The exhaust pipe cover 47 is provided below the pair of attraction pads 121 and 122 constituting the second substrate holder 12.

The friction body 50 rubs against the lower surface of the substrate W. The friction body 50 is a brush or sponge. The friction body 50 has, for example, a cylindrical shape, and the upper surface of the friction body 50 is oriented horizontally. The upper surface of the friction body 50 is smaller in size than the lower surface of the substrate W.

The friction body 50 is rotated by a rotation motor 51. The rotation motor 51 is provided at one end of an arm 53. The friction body mover 55 is provided at the other end of the arm 53. The friction body mover 55 moves the friction body 50 in the horizontal and vertical directions through the arm 53.

The controller 90 is, for example, a computer, and as illustrated in FIG. 1, includes a computing unit 91 such as a central processing unit (CPU), and a storage 92 such as a memory. The storage 92 stores programs that control various processes executed in the substrate processing apparatus 1. The controller 90 causes the computing unit 91 to execute the programs stored in the storage 92, thereby controlling the operation of the substrate processing apparatus 1.

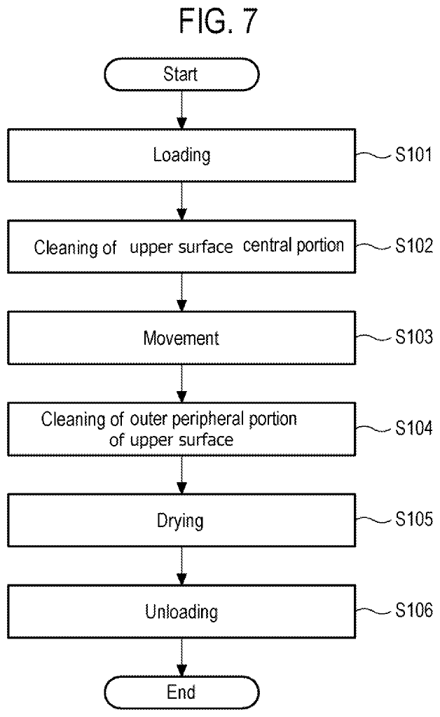

Next, an example of a substrate processing method using the substrate processing apparatus 1 will be described with reference to FIG. 7. As illustrated in FIG. 7, the substrate processing method includes steps S101 to S106. Steps S101 to S106 are performed under the control of the controller 90.

Step S101 includes loading the substrate W into the substrate processing apparatus 1 from the outside. First, a transfer arm (not illustrated) transfers the substrate W to above the cup 20 and waits above the cup 20. At this time, when viewed from above, the center of the substrate W, the center of the first substrate holder 11, and the center of the cup 20 overlap, as illustrated in FIG. 1.

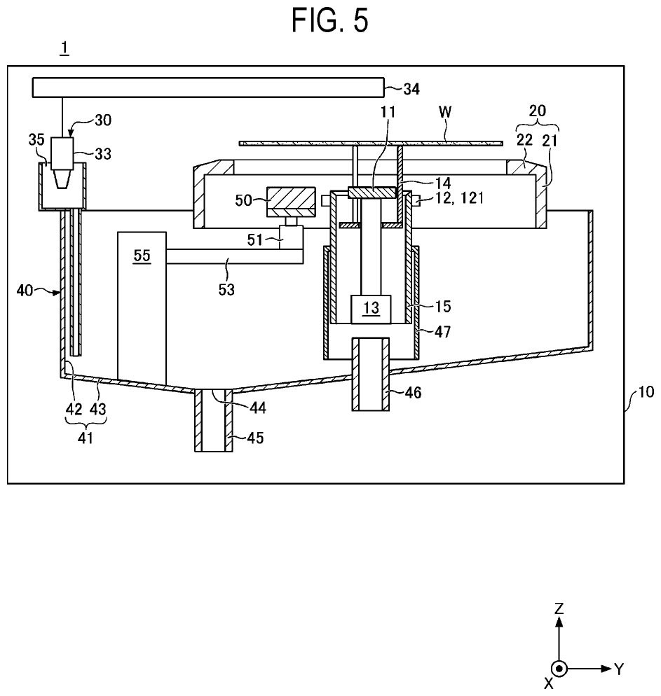

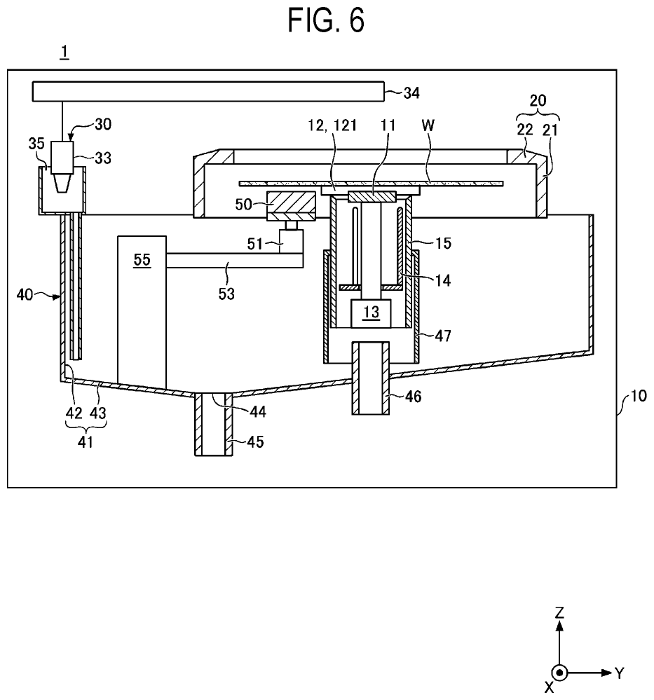

Subsequently, the plurality of lifting pins 14 are moved up to lift the substrate W from the transfer arm (not illustrated) (see FIG. 5). Subsequently, once the transfer arm is withdrawn from the substrate processing apparatus 1, the cup 20 is moved up, and the plurality of lifting pins 14 are moved down to deliver the substrate W to the second substrate holder 12 (see FIG. 6). Subsequently, the second substrate holder 12 attracts the outer peripheral portion of the lower surface of the substrate W.

Step S102 includes cleaning the central portion of the lower surface of the substrate W while the outer peripheral portion of the lower surface of the substrate W is attracted by the second substrate holder 12 (see FIG. 4). The lower nozzles 31 and 32 supply the processing liquid to the lower surface of the substrate W, and the friction body mover 55 moves the friction body 50 in the horizontal direction while pressing the friction body 50 against the central portion of the lower surface of the substrate W. Further, the movement drive 25 moves the second substrate holder 12 together with the cup 20 in the horizontal direction. In addition, the movement direction of the friction body 50 intersects with the movement direction of the cup 20.

Step S103 includes moving the substrate W from the second substrate holder 12 to the first substrate holder 11. First, the cup 20 may be moved in the horizontal direction to a position where the center of the substrate W, the center of the first substrate holder 11, and the center of the cup 20 overlap when viewed from above, as illustrated in FIG. 1. Thereafter, the movement drive 25 moves the cup 20 downward, enabling the second substrate holder 12 to deliver the substrate W to the first substrate holder 11. The second substrate holder 12 releases the attraction of the outer peripheral portion of the lower surface of the substrate W, while the first substrate holder 11 attracts the central portion of the lower surface of the substrate W.

Step S104 includes cleaning the outer peripheral portion of the lower surface of the substrate W while the central portion of the lower surface of the substrate W is attracted by the first substrate holder 11 (see FIG. 2). The lower nozzles 31 and 32 supply the processing liquid to the lower surface of the substrate W, and the friction body mover 55 moves the friction body 50 in the horizontal direction while pressing the friction body 50 against the outer peripheral portion of the lower surface of the substrate W. Further, the rotation drive 13 rotates the substrate W together with the first substrate holder 11.

In addition, while the rotation drive 13 rotates the substrate W together with the first substrate holder 11, the upper surface of the substrate W is subjected to cleaning. For example, the upper nozzle 33 supplies the processing liquid to the upper surface of the substrate W. The upper nozzle 33 may supply the processing liquid to the central portion of the upper surface of the substrate W, or may be moved in the radial direction of the substrate W to supply the processing liquid to the entire substrate W throughout the radial direction. Further, a second friction body (not illustrated) may be provided to rub against the upper surface of the substrate W. Further, a third friction body (not illustrated) may be provided to rub against the bevel of the substrate W.

Step S105 includes drying the substrate W. For example, the rotation drive 13 rotates the first substrate holder 11 at high speed, thereby shaking off the processing liquid adhering to the substrate W.

Step S106 includes unloading the substrate W from the interior of the substrate processing apparatus 1 to the outside. First, the first substrate holder 11 releases the attraction of the substrate W and moves up the plurality of lifting pins 14, so that the plurality of lifting pins 14 lift the substrate W from the first substrate holder 11. Subsequently, the transfer arm is introduced to the interior of the substrate processing apparatus 1 from the outside and waits above the cup 20. Subsequently, the plurality of lifting pins 14 are moved down to deliver the substrate W to the transfer arm. Thereafter, the transfer arm is withdrawn from the substrate processing apparatus 1 while holding the substrate W.

When the first substrate holder 11 holds the substrate W, there may be a case where a contaminant on the substrate W is transferred to the first substrate holder 11, thereby causing the first substrate holder 11 to become contaminated. Thereafter, when the first substrate holder 11 holds another substrate W, the respective substrate W also becomes contaminated. Therefore, in the related art, in order to remove a contaminant from the first substrate holder 11, an operator periodically wipes away the contaminant from the first substrate holder 11 with a fiber wipe such as a waste cloth, or prepares a large number of clean substrates W to bring them into contact with the first substrate holder 11 one after another.

According to the present embodiment, although it will be described in detail later, with the use of the substrate processing apparatus 1 including both the first substrate holder 11 and the second substrate holder 12, the contact between the first substrate holder 11 and the substrate W is repeated by changing a contact position of the substrate W with the first substrate holder 11. Such a change in contact position is performed while the second substrate holder 12 holds the substrate W. Further, the change in contact position is achieved by rotating the first substrate holder 11 or by moving the first substrate holder 11 and the second substrate holder 12 relative to each other. A contaminant may be transferred from the first substrate holder 11 to the substrate W at a new uncontaminated contact position. Accordingly, the number of substrates W to be used may be reduced, and the efficiency of contaminant removal from the first substrate holder 11 may be enhanced. Further, reducing the number of substrates W to be used may result in a reduction in the number of times the substrates W are transferred, and the time required for maintenance may also be shortened.

In addition, as will be described later, the contents of the present disclosure are also applicable to the cleaning of the second substrate holder 12. Specifically, the contact between the second substrate holder 12 and the substrate W is repeated by changing a contact position of the substrate W with the second substrate holder 12. Such a change in contact position is performed while the first substrate holder 11 holds the substrate W. Further, the change in contact position is achieved by rotating the first substrate holder 11 or by moving the first substrate holder 11 and the second substrate holder 12 relative to each other. A contaminant may be transferred from the second substrate holder 12 to the substrate W at a new uncontaminated contact position. Accordingly, the number of substrates W to be used may be reduced, and the efficiency of contaminant removal from the second substrate holder 12 may be enhanced. Further, reducing the number of substrates W to be used may result in a reduction in the number of times the substrates W are transferred, and the time required for maintenance may also be shortened.

In addition, as will be described later, the contents of the present disclosure are also applicable to the cleaning of the lifting pins 14. Specifically, the contact between the lifting pins 14 and the substrate W is repeated by changing a contact position of the substrate W with the lifting pins 14. Such a change in contact position is performed while the first substrate holder 11 or the second substrate holder 12 holds the substrate W. Further, the change in contact position is achieved by rotating the first substrate holder 11 or by moving the first substrate holder 11 and the second substrate holder 12 relative to each other. A contaminant may be transferred from the lifting pins 14 to the substrate W at a new uncontaminated contact position. Accordingly, the number of substrates W to be used may be reduced, and the efficiency of contaminant removal from the lifting pins 14 may be enhanced. Further, reducing the number of substrates W to be used may result in a reduction in the number of times the substrates W are transferred, and the time required for maintenance may also be shortened.

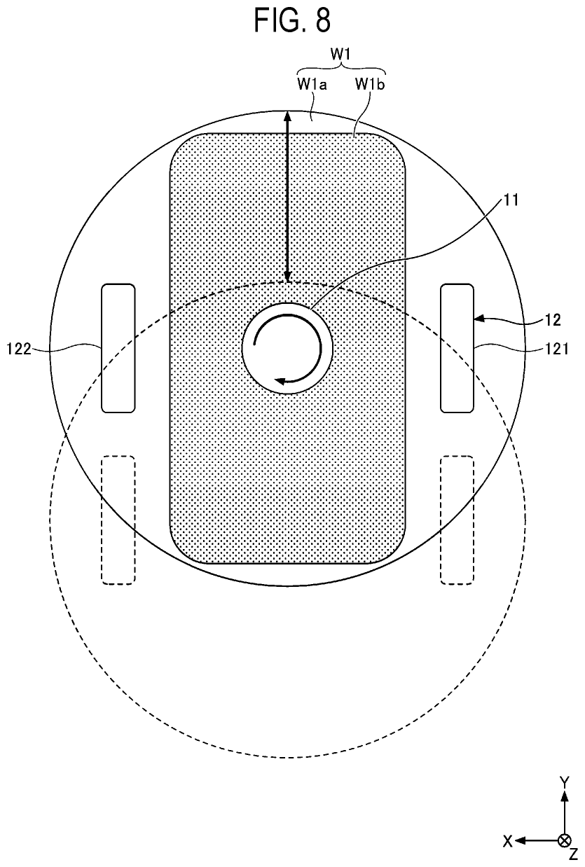

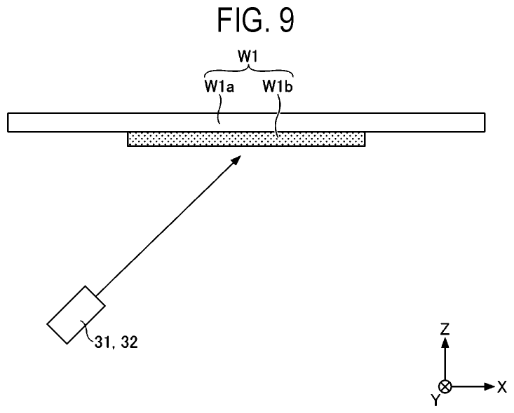

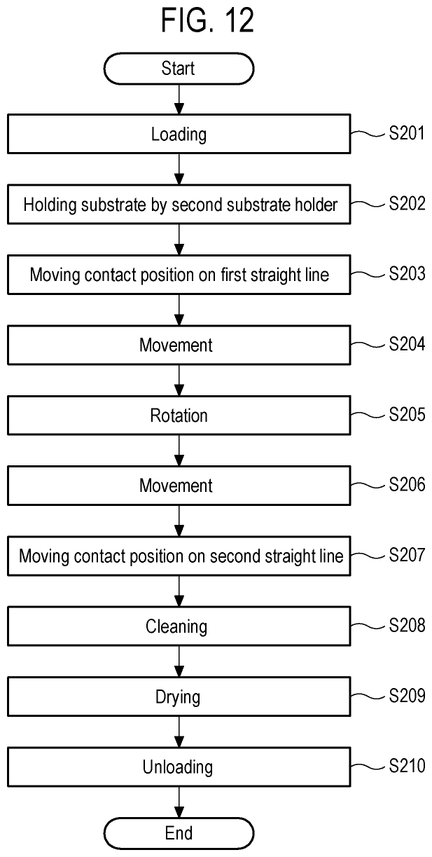

Next, an exemplary cleaning of the first substrate holder 11 will be described with reference to FIGS. 8 to 12. As illustrated in FIG. 12, a substrate processing method includes steps S201 to S210. Steps S201 to S210 are periodically performed under the control of the controller 90. A substrate W1 used in steps S201 to S210 includes, for example, a supporting substrate W1a and a removal layer W1b, as illustrated in FIG. 9.

The supporting substrate W1a supports the removal layer W1b. The supporting substrate W1a is a semiconductor substrate or a glass substrate. The removal layer W1b comes into contact with the first substrate holder 11 to remove contaminants. The removal layer W1b is, for example, a fiber wipe such as a waste cloth, and adheres to the supporting substrate W1a using an adhesive or the like. The fiber wipe wipes away contaminants from the first substrate holder 11.

In addition, the removal layer W1b is not limited to the fiber wipe. The removal layer W1b may also be a brush, sponge, adhesive film, or resin film. The brush or sponge wipes away contaminants, similarly to the fiber wipe. On the other hand, the adhesive film or resin film attracts contaminants by virtue of an adhesive force or electrostatic force to peel off the same from the first substrate holder 11.

The adhesive film or resin film is movable relative to the first substrate holder 11 while being spaced apart from the first substrate holder 11. Unlike the adhesive film or resin film, the fiber wipe, brush, or sponge is movable relative to the first substrate holder 11 while in a state of not only being spaced apart from the first substrate holder 11 but also being pressed against the first substrate holder 11.

The fiber wipe, brush, or sponge may also be used in a wet state with a liquid such as pure water or an organic solvent. The liquid is supplied with the lower nozzles 31 and 32, for example, as illustrated in FIG. 9. The lower nozzles 31 and 32 may supply the liquid only to a portion of the removal layer W1b. Wet wiping may be performed on a portion of the removal layer W1b, and subsequently, dry wiping may be performed on the remaining portion of the removal layer W1b.

In addition, the substrate W1 used in steps S201 to S210 may also be a bare wafer. The bare wafer is made entirely of, for example, silicon, compound semiconductors, or glass. The bare wafer uses an electrostatic force to attract contaminants and peel off the same from the first substrate holder 11.

Step S201 includes loading the substrate W1 into the substrate processing apparatus 1 from the outside. First, a transfer arm (not illustrated) transfers the substrate W1 to above the cup 20 and waits above the cup 20. At this time, when viewed from above, the center of the substrate W1, the center of the first substrate holder 11, and the center of the cup 20 overlap, as illustrated in FIG. 1.

Subsequently, the plurality of lifting pins 14 are moved up to lift the substrate W1 from the transfer arm (not illustrated). Subsequently, once the transfer arm is withdrawn from the substrate processing apparatus 1, the cup 20 is moved up, and the plurality of lifting pins 14 are moved down to deliver the substrate W1 to the second substrate holder 12.

In step S202, the second substrate holder 12 holds the substrate W1. As illustrated in FIG. 8, the second substrate holder 12 attracts the outer peripheral portion of the lower surface of the substrate W1. The removal layer W1b is not partially provided on the outer peripheral portion of the lower surface of the substrate W1, and the second substrate holder 12 attracts the supporting substrate W1a without interfering with the removal layer W1b. This allows the second substrate holder 12 to strongly attract the substrate W1.

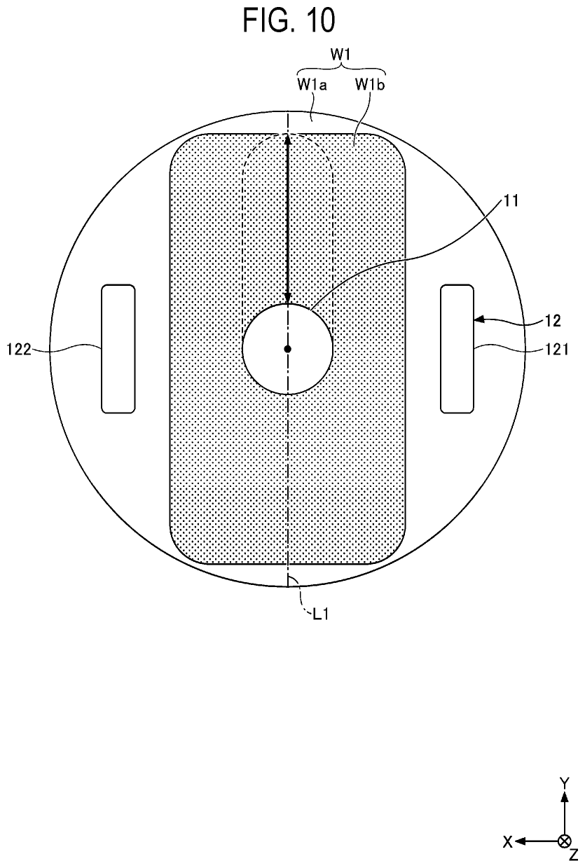

Step S203 includes shifting a contact position of the substrate W1 with the first substrate holder 11 in a plan view on a first straight line L1 passing through the center of the substrate W1 by moving, by the movement drive 25, the substrate W1 together with the second substrate holder 12 in the Y-axis direction (see FIG. 10). The movement direction may be either the positive Y-axis direction, the negative Y-axis direction, or both. Contaminants may be transferred from the first substrate holder 11 to the substrate W1 at a new uncontaminated contact position.

When the removal layer W1b is a fiber wipe, brush, or sponge, the movement drive 25 maintains the second substrate holder 12 at a constant height, thereby moving the second substrate holder 12 in the Y-axis direction while pressing the substrate W1 against the first substrate holder 11. By friction generated during the movement, the contaminants are removed. In this case, the rotation drive 13 may preferably rotate the first substrate holder 11. Such a rotation and movement may be combined with each other to remove the contaminants.

When the removal layer W1b is an adhesive film or resin film, or when there is no removal layer W1b and the substrate W1 is a bare wafer, the movement drive 25 repeats pressing the substrate W1 against the first substrate holder 11, separating the substrate W1 from the first substrate holder 11, and moving the second substrate holder 12 in the Y-axis direction in this order.

Further, when the removal layer W1b is an adhesive film or resin film, or when there is no removal layer W1b and the substrate W1 is a bare wafer, the manifestation of the attractive force by the first attractive-force applier 71, the dissipation of the attractive force by the first attractive-force applier 71, and the movement of the second substrate holder 12 in the Y-axis direction by the movement drive 25 may be repeated in this order.

The manifestation of the attractive force by the first attractive-force applier 71 occurs in combination with the movement drive 25 pressing the substrate W1 against the first substrate holder 11. The manifestation of the attractive force enables stronger pressing, making it easier to remove contaminants. Further, the dissipation of the attractive force by the first attractive-force applier 71 occurs in combination with the movement drive 25 moving the substrate W1 away from the first substrate holder 11.

Step S204 includes moving the substrate W1 from the second substrate holder 12 to the first substrate holder 11. First, the cup 20 may be moved in the horizontal direction to a position where the center of the substrate W1, the center of the first substrate holder 11, and the center of the cup 20 overlap when viewed from above, as illustrated in FIG. 1. Thereafter, when the movement drive 25 moves down the cup 20, the second substrate holder 12 delivers the substrate W1 to the first substrate holder 11. The second substrate holder 12 releases the attraction of the outer peripheral portion of the lower surface of the substrate W, while the first substrate holder 11 attracts the central portion of the lower surface of the substrate W.

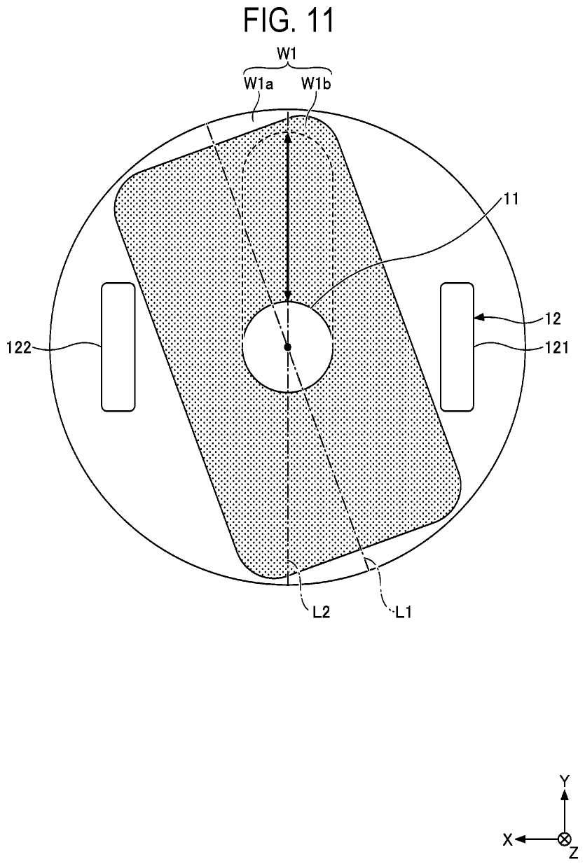

Step S205 includes rotating the substrate W1 together with the first substrate holder 11 by the rotation drive 13. As illustrated in FIG. 11, the rotation drive 13 rotates the substrate W1 such that the first straight line L1 is inclined with respect to the movement direction (Y-axis direction) of the substrate W1 in a plan view. In addition, although not illustrated, the rotation drive 13 may rotate the substrate W1 such that the first straight line L1 is perpendicular to the movement direction (Y-axis direction) of the substrate W1.

Step S206 includes moving the substrate W1 from the first substrate holder 11 to the second substrate holder 12. For example, when the movement drive 25 moves up the cup 20, the second substrate holder 12 receives the substrate W1 from the first substrate holder 11. The first substrate holder 11 releases the attraction of the central portion of the lower surface of the substrate W1, while the second substrate holder 12 attracts the outer peripheral portion of the lower surface of the substrate W1.

Like step S203, step S207 includes shifting the contact position of the substrate W1 with the first substrate holder 11 in a plan view on a second straight line L2 passing through the center of the substrate W1 by moving, by the movement drive 25, the substrate W1 together with the second substrate holder 12 in the Y-axis direction (see FIG. 11). The second straight line L2 is different from the first straight line L1, and intersects with the first straight line L1 at the center of the substrate W1. Contaminants may be transferred from the first substrate holder 11 to the substrate W1 at a new uncontaminated contact position.

Step S208 includes cleaning the substrate W1 by a cleaner. The cleaner includes a nozzle such as, for example, the lower nozzles 31 and 32. The nozzle supplies a processing liquid (including a mixed fluid of the processing liquid and gas) to the substrate W1, thereby washing away contaminants from the substrate W1. Pure water is used as the processing liquid, but an alkaline or acidic chemical liquid followed by the pure water may also be used in this order. Removing contaminants before unloading the substrate W1 may prevent the carryover of contaminants. The cleaner may include the friction body 50 such that the friction body 50 removes the contaminants adhering to the substrate W1 by friction.

Step S209 includes drying the substrate W1 by a dryer. The dryer includes a nozzle such as, for example, the gas discharge ring 15. The nozzle supplies a gas to the substrate W1, thereby drying the substrate W1. By dropping liquid droplets on the substrate W1 before unloading the substrate W1, it is possible to prevent the carryover of the liquid droplets. In addition, by supplying a gas to the substrate W1, it is possible to remove contaminants from the substrate W1. Steps S208 and S209 may be performed simultaneously.

Step S210 includes unloading the substrate W1 from the interior of the substrate processing apparatus 1 to the outside. First, the cup 20 may be moved in the horizontal direction to a position where the center of the substrate W1, the center of the first substrate holder 11, and the center of the cup 20 overlap when viewed from above, as illustrated in FIG. 1. Thereafter, the second substrate holder 12 releases the attraction of the substrate W1, and the plurality of lifting pins 14 are moved up to lift the substrate W from the second substrate holder 12. Subsequently, the transfer arm is introduced to the interior of the substrate processing apparatus 1 from the outside and waits above the cup 20. Next, the plurality of lifting pins 14 are moved down to deliver the substrate W1 to the transfer arm. Thereafter, the transfer arm is withdrawn from the substrate processing apparatus 1 while holding the substrate W1.

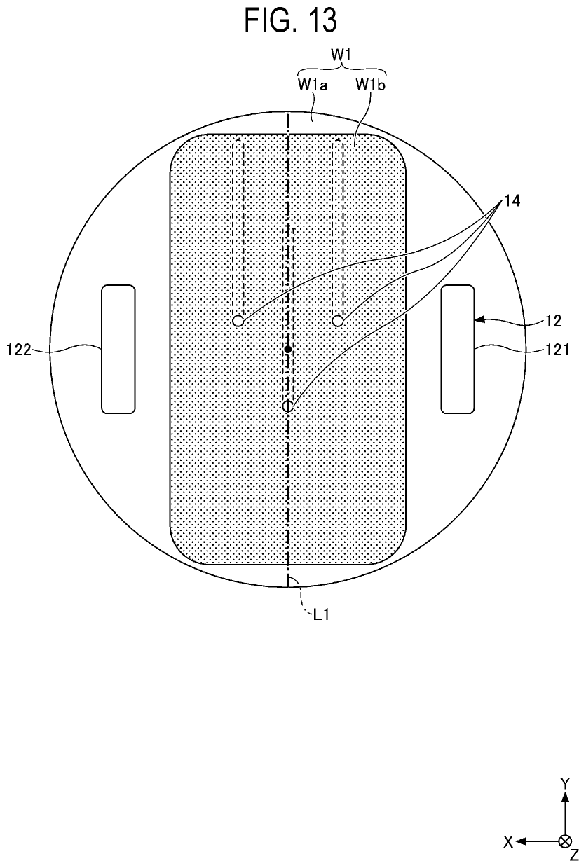

Next, an exemplary cleaning of the lifting pins 14 will be described with reference to FIG. 13. The cleaning of the lifting pins 14 is performed similarly to the cleaning of the first substrate holder 11. For example, the movement drive 25 moves the substrate W1 together with the second substrate holder 12 in the Y-axis direction, thereby changing a contact position of the substrate W1 with the lifting pins 14 in a plan view. The movement direction of the contact position may be either the positive Y-axis direction, the negative Y-axis direction, or both. Contaminants may be transferred from the lifting pins 14 to the substrate W1 at a new uncontaminated contact position.

When the removal layer W1b is a fiber wipe, brush, or sponge, the movement drive 25 maintains the second substrate holder 12 at a constant height, thereby moving the second substrate holder 12 in the Y-axis direction while pressing the substrate W1 against the lifting pins 14. By friction generated during such a movement, contaminants may be removed.

When the removal layer W1b is an adhesive film or resin film, or when there is no removal layer W1b and the substrate W1 is a bare wafer, the movement drive 25 repeats pressing the substrate W1 against the lifting pins 14, separating the substrate W1 from the lifting pins 14, and moving the second substrate holder 12 in the Y-axis direction in this order.

Like the cleaning of the first substrate holder 11, the cleaning of the lifting pins 14 may include steps S204 to S206 (such as rotating the substrate W1 together with the first substrate holder 11 by the rotation drive 13), and then, may also include moving, by the movement drive 25, the substrate W1 together with the second substrate holder 12 in the Y-axis direction. Contaminants may be transferred from the lifting pins 14 to the substrate W1 at a new uncontaminated contact position.

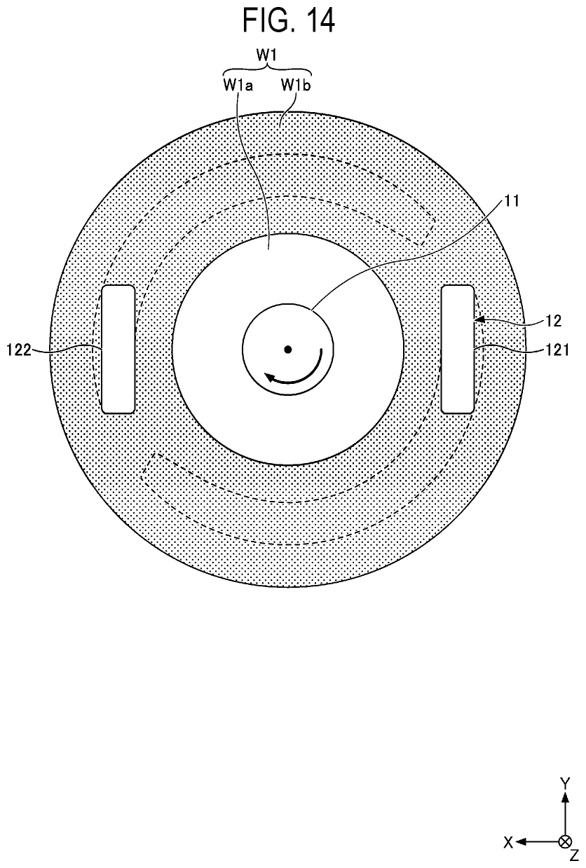

Next, an exemplary cleaning of the second substrate holder 12 will be described with reference to FIG. 14. In the cleaning of the first substrate holder 11, the second substrate holder 12 holds the substrate W1, while in the cleaning of the second substrate holder 12, the first substrate holder 11 holds the substrate W1. Therefore, the removal layer W1b is not provided on the central portion of the lower surface of the substrate W1, and the first substrate holder 11 attracts the supporting substrate W1a without interfering with the removal layer W1b. This allows the first substrate holder 11 to strongly attract the substrate W1. The removal layer W1b is provided on, for example, the outer peripheral portion of the lower surface of the substrate W1.

The rotation drive 13 rotates the substrate W1 together with the first substrate holder 11, thereby changing a contact position of the substrate W1 with the second substrate holder 12 in a plan view. The movement direction of the contact position may be either clockwise, counterclockwise, or both. Contaminants may be transferred from the second substrate holder 12 to the substrate W1 at a new uncontaminated contact position.

When the removal layer W1b is a fiber wipe, brush, or sponge, the movement drive 25 maintains the second substrate holder 12 at a constant height, thereby rotating, by the rotation drive 13, the substrate W1 together with the first substrate holder 11 while pressing the substrate W1 against the second substrate holder 12. By friction generated during such a rotation, contaminants may be removed.

When the removal layer W1b is an adhesive film or resin film, or when there is no removal layer W1b and the substrate W1 is a bare wafer, pressing the substrate W1 against the second substrate holder 12 by the movement drive 25, separating the second substrate holder 12 from the substrate W1 by the movement drive 25, and rotating the substrate W1 together with the first substrate holder 11 by the rotation drive 13 may be repeated in this order.

Further, when the removal layer W1b is an adhesive film or resin film, or when there is no removal layer W1b and the substrate W1 is a bare wafer, the manifestation of the attractive force by the second attractive-force applier 72, the dissipation of the attractive force by the second attractive-force applier 72, and rotating the substrate W1 together with the first substrate holder 11 by the rotation drive 13 may be repeated in this order.

The manifestation of the attractive force by the second attractive-force applier 72 occurs in combination with the movement drive 25 pressing the substrate W1 against the second substrate holder 12. The manifestation of the attractive force enables stronger pressing, making it easier to remove contaminants. Further, the dissipation of the attractive force by the second attractive-force applier 72 occurs in combination with the movement drive 25 moving the substrate W1 away from the second substrate holder 12.

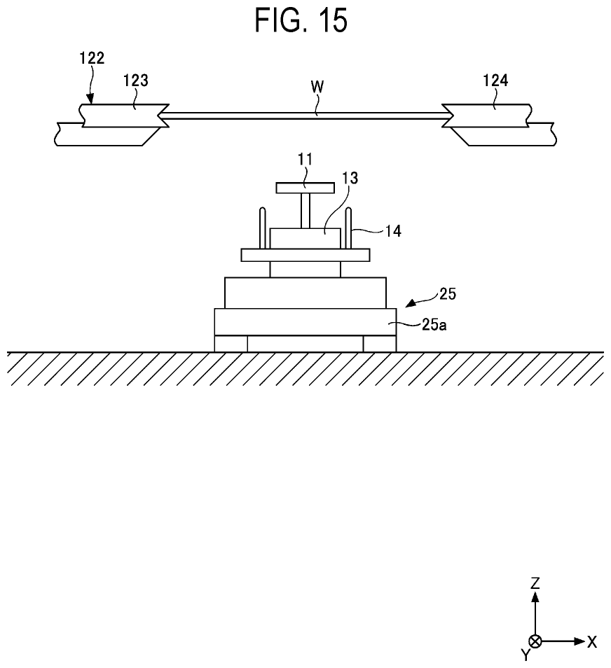

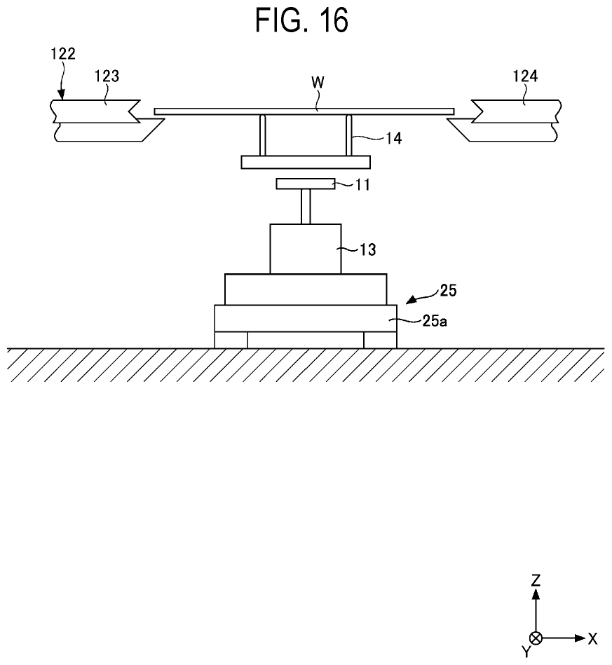

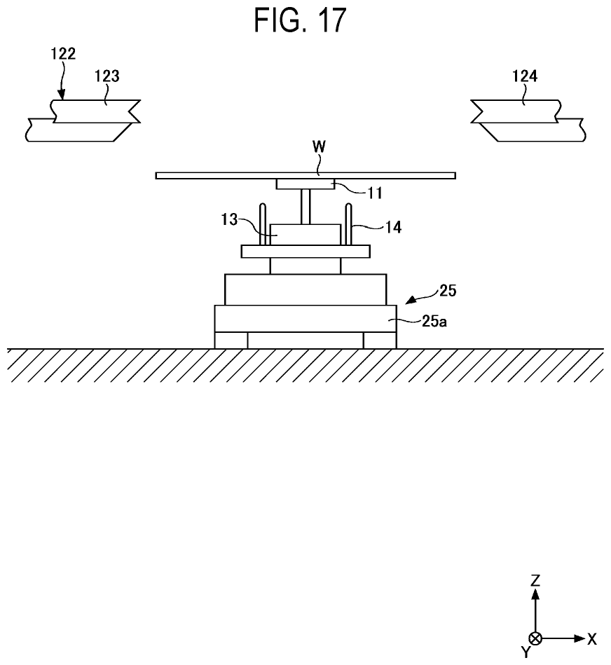

Next, a first modification of the first substrate holder 11 and the second substrate holder 12 will be described with reference to FIGS. 15 to 17. The first substrate holder 11 attracts the central portion of the lower surface of the substrate W as in the above embodiment (see FIG. 17). The first substrate holder 11 is constituted with, for example, a spin chuck. The rotation drive 13 rotates the first substrate holder 11 about a vertical rotation central axis. The rotation drive 13 rotates the substrate W together with the first substrate holder 11. The movement drive 25 moves the first substrate holder 11 in the horizontal direction (Y-axis direction) perpendicular to the rotation central axis of the first substrate holder 11. The movement drive 25 includes a Y-axis slider 25a which is movable in the Y-axis direction, and both the rotation drive 13 and the first substrate holder 11 are mounted on the Y-axis slider 25a.

On the other hand, unlike the above embodiment, the second substrate holder 12 mechanically holds the outer periphery of the substrate W at a plurality of locations (see FIG. 15). The second substrate holder 12 is positioned higher than the first substrate holder 11. The second substrate holder 12 includes a pair of movable hooks 123 and 124 which hold the substrate W while sandwiching the substrate W therebetween. The pair of movable hooks 123 and 124 are arranged at an interval in the X-axis direction to be in contact with or spaced apart from each other.

The plurality of lifting pins 14 are moved up and down around the first substrate holder 11, thereby making the transfer of the substrate W between the first substrate holder 11 or the second substrate holder 12 and a transfer arm (not illustrated). The plurality of lifting pins 14 are mounted on the Y-axis slider 25a and are moved in the Y-axis direction together with the first substrate holder 11. In addition, the plurality of lifting pins 14 may be provided at intervals in the Y-axis direction without being mounted on the Y-axis slider 25a.

The substrate W is delivered from an external transfer arm to the lifting pins 14, and is then delivered from the lifting pins 14 to the second substrate holder 12. In the state where the second substrate holder 12 holds the outer periphery of the substrate W, a friction body (not illustrated) cleans the central portion of the lower surface of the substrate W. Thereafter, the substrate W is delivered from the second substrate holder 12 to the lifting pins 14, and is then delivered from the lifting pins 14 to the first substrate holder 11. In the state where the first substrate holder 11 holds the central portion of the lower surface of the substrate W, a friction body (not illustrated) cleans the outer peripheral portion of the lower surface of the substrate W. At this time, the substrate W is rotated together with the first substrate holder 11.

Also in this modification, as in the above embodiment, it is possible to perform the cleaning of the first substrate holder 11, the cleaning of the second substrate holder 12, or the cleaning of the lifting pins 14. These cleaning operations include rotating the substrate W1 together with the first substrate holder 11 or moving the first substrate holder 11 and the second substrate holder 12 relative to each other. The first substrate holder 11 or the second substrate holder 12 may be moved in the Z-axis direction.

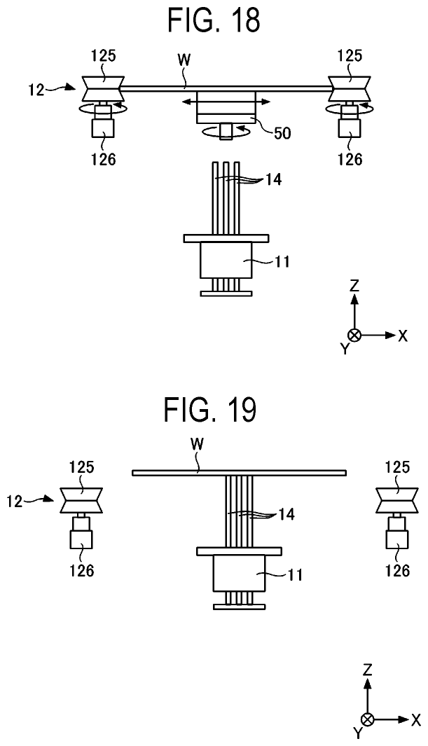

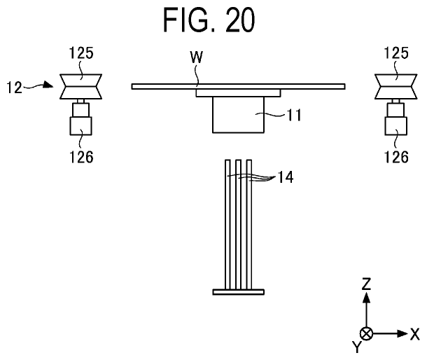

Next, a second modification of the first substrate holder 11 and the second substrate holder 12 will be described with reference to FIGS. 18 to 20. The first substrate holder 11 attracts the central portion of the lower surface of the substrate W as in the above embodiment (see FIG. 20). The first substrate holder 11 is constituted with, for example, a spin chuck. The rotation drive 13 rotates the first substrate holder 11 about a vertical rotation central axis. The rotation drive 13 rotates the substrate W together with the first substrate holder 11.

On the other hand, unlike the above embodiment, the second substrate holder 12 mechanically holds the outer periphery of the substrate W at a plurality of locations (see FIG. 18). The second substrate holder 12 includes, for example, a plurality of (e.g., four) rotatable tops 125. Each rotatable top 125 is constituted with a horizontal disk. A wedge-shaped recess is formed on an outer peripheral surface of the disk throughout the circumferential direction. The wedge-shaped recess holds the outer periphery of the substrate W while vertically sandwiching the outer periphery therein. For example, two rotatable tops 125 are provided on each of a pair of arms 126.

The pair of arms 126 are arranged with the substrate W interposed therebetween and approach each other or are separated apart from each other. When the pair of arms 126 approach each other, the plurality of rotatable tops 125 hold the outer periphery of the substrate W by vertically sandwiching the outer periphery in the respective recesses thereof. In this state, the substrate W may be rotated by individually rotating the plurality of rotatable tops 125 about their axes. Thereafter, when the rotation of the substrate W is stopped and the pair of arms 126 are separated from each other, the mechanical holding of the substrate W by the plurality of rotatable tops 125 is released.

The plurality of lifting pins 14 are inserted into through-holes that pass through the first substrate holder 11 in the vertical direction, and receive the substrate W at a position higher than the first substrate holder 11. The plurality of lifting pins 14 are moved up and down to transfer the substrate W between the first substrate holder 11 and a transfer arm (not illustrated).

The substrate W is delivered from an external transfer arm to the lifting pins 14, and is then delivered from the lifting pins 14 to the second substrate holder 12 through the first substrate holder 11. In the state where the second substrate holder 12 holds the outer periphery of the substrate W, the friction body 50 cleans the central portion of the lower surface of the substrate W. At this time, the plurality of rotatable tops 125 are individually rotated about their axes, thereby causing the substrate W to be rotated. Thereafter, the substrate W is delivered from the second substrate holder 12 to the first substrate holder 11. In the state where the first substrate holder 11 holds the central portion of the lower surface of the substrate W, the friction body 50 cleans the outer peripheral portion of the lower surface of the substrate W. At this time, the substrate W is rotated together with the first substrate holder 11.

Also in this modification, as in the above embodiment, it is possible to perform the cleaning of the first substrate holder 11, the cleaning of the second substrate holder 12, or the cleaning of the lifting pins 14. These cleaning operations include rotating the substrate W1 together with the first substrate holder 11, or moving the first substrate holder 11 and the second substrate holder 12 relative to each other. The first substrate holder 11 or the second substrate holder 12 may be moved in the Z-axis direction.

According to one aspect of the present disclosure, it is possible to improve the efficiency of removing contaminants from a substrate holder.

Although the embodiments of the substrate processing apparatus and the substrate processing method according to the present disclosure have been described above, the present disclosure is not limited to the above embodiments. Various changes, modifications, substitutions, additions, deletions, and combinations are possible within the scope set forth in the claims. These also naturally belong to the technical scope of the present disclosure.

What is claimed is:

1. A substrate processing apparatus that processes a substrate with a processing liquid, comprising:
a processing container;
a first substrate holder configured to horizontally hold the substrate inside the processing container;
a rotation drive configured to rotate the first substrate holder about a vertical rotation central axis;
a second substrate holder configured to horizontally hold the substrate inside the processing container;
a movement drive configured to move the first substrate holder and the second substrate holder relative to each other; and
a controller configured to control the rotation drive and the movement drive,
wherein the controller performs a first control to repeat contact between the first substrate holder and the substrate by changing a first contact position of the substrate with the first substrate holder.

2. The substrate processing apparatus of claim 1, wherein the controller performs a second control to shift the first contact position of the substrate with the first substrate holder in a plan view on a first straight line passing through a center of the substrate.

3. The substrate processing apparatus of claim 2, wherein the controller performs a third control to shift the first contact position of the substrate with the first substrate holder in the plan view on a second straight line passing through the center of the substrate, the second straight line being different from the first straight line.

4. The substrate processing apparatus of claim 1, further comprising: a first attractive-force applier configured to apply, to the first substrate holder, an attractive force that attracts the substrate,
wherein the controller repeatedly performs a fourth control to manifest the attractive force, a fifth control to dissipate the attractive force, and a sixth control to change the contact position of the substrate with the first substrate holder.

5. The substrate processing apparatus of claim 1, wherein the movement drive is configured to move the second substrate holder in a horizontal direction perpendicular to the rotation central axis of the first substrate holder and in a vertical direction.

6. The substrate processing apparatus of claim 1, wherein the movement drive is configured to move the first substrate holder in a horizontal direction perpendicular to the rotation central axis of the first substrate holder.

7. The substrate processing apparatus of claim 1, wherein the second substrate holder comes into contact with a lower surface of the substrate.

8. The substrate processing apparatus of claim 1, wherein the second substrate holder comes into contact with an outer periphery of the substrate.

9. The substrate processing apparatus of claim 1, wherein the substrate includes a removal layer that comes into contact with the first substrate holder to remove contaminants, and
wherein the removal layer is a fiber wipe, a brush, a sponge, an adhesive film, or a resin film.

10. The substrate processing apparatus of claim 1, further comprising: a cleaner configured to clean the substrate after the first contact position of the substrate with the first substrate holder in a plan view is shifted.

11. The substrate processing apparatus of claim 1, wherein the controller performs a seventh control to repeat a contact between the second substrate holder and the substrate by changing a second contact position of the substrate with the second substrate holder.

12. The substrate processing apparatus of claim 1, further comprising: a plurality of lifting pins configured to raise or lower the substrate relative to the first substrate holder or the second substrate holder,
wherein the controller performs an eighth control to repeat contact between the plurality of lifting pins and the substrate by changing a third contact position of the substrate with the plurality of lifting pins.

13. The substrate processing apparatus of claim 2, further comprising: a first attractive-force applier configured to apply, to the first substrate holder, an attractive force that attracts the substrate,
wherein the controller repeatedly performs a third control to manifest the attractive force, a fourth control to dissipate the attractive force, and a fifth control to change the contact position of the substrate with the first substrate holder.

14. The substrate processing apparatus of claim 2, wherein the movement drive is configured to move the second substrate holder in a horizontal direction perpendicular to the rotation central axis of the first substrate holder and in a vertical direction.

15. The substrate processing apparatus of claim 2, wherein the second substrate holder comes into contact with a lower surface of the substrate.

16. A substrate processing method of processing a substrate with a processing liquid using a substrate processing apparatus,
wherein the substrate processing apparatus includes a processing container, a first substrate holder configured to horizontally hold the substrate inside the processing container, a rotation drive configured to rotate the first substrate holder about a vertical rotation central axis, a second substrate holder configured to horizontally hold the substrate inside the processing container, and a movement drive configured to move the first substrate holder and the second substrate holder relative to each other,
the substrate processing method comprising:
repeating contact between the first substrate holder and the substrate by changing a contact position of the substrate with the first substrate holder.

17. The substrate processing method of claim 16, further comprising: shifting the contact position of the substrate with the first substrate holder in a plan view on a first straight line passing through a center of the substrate.

18. The substrate processing method of claim 17, further comprising: shifting the contact position of the substrate with the first substrate holder in a plan view on a second straight line passing through the center of the substrate, the second straight line being different from the first straight line.

19. The substrate processing method of claim 16, further comprising: repeating a cycle including attracting the substrate by the first substrate holder, releasing the attracting of the substrate, and changing the contact position of the substrate with the first substrate holder.

20. A substrate used to clean a substrate holder configured to hold the substrate to be processed with a processing liquid, comprising:
a removal layer that comes into contact with the substrate holder to remove contaminants,
wherein the removal layer is a fiber wipe, a brush, a sponge, an adhesive film, or a resin film.
